(19) United States
(12) Patent Application Publication
(10) Pub. No.: US 2010/0238705 A1
(43) Pub. Date: Sep. 23, 2010

(54) NONVOLATILE MEMORY DEVICE AND METHOD SYSTEM INCLUDING THE SAME

(76) Inventors: Yong June Kim, Seoul (KR); Jaehong Kim, Seoul (KR); Junjin Kong, Yongin-si (KR)

Correspondence Address: F. CHAU & ASSOCIATES, LLC, 130 WOODBURY ROAD, WOODBURY, NY, 11797, US

(21) Appl. No.: 12/698,720

(22) Filed: Feb. 2, 2010

(30) Foreign Application Priority Data
Mar. 23, 2009 (KR) 10-2009-0024628

(51) Int. Cl. G11C 11/00; G11C 7/00

(52) U.S. Cl. 365/148; 365/189.14

(57) ABSTRACT

A nonvolatile memory device performs interleaving of data to be stored in each wordline (memory page), or of data to be stored in multiple wordlines (memory pages). The NVM includes a memory cell array, a storage circuit of a de-interleaving circuit, and a read/write circuit. The storage circuit of the de-interleaving circuit is configured to store program data to be written interleaved into the memory cell array. The read/write circuit is configured to control the interleaved/deinterleaved data input/output between the memory cell array and the storage circuit. The write operation unit size may be the same or different from the read operation unit size. The storage circuit stores the program data of integer k times of a common divisor of a read operation unit size and a write operation unit size of the read/write circuit, wherein k may equal ‘m’ (the number of bits stored in each memory cell of the NVM).

### CROSS-REFERENCE TO RELATED APPLICATIONS

This U.S. application claims priority, under 35 U.S.C. §119, of Korean Patent Application No. 10-2009-0024628, filed on Mar. 23, 2009, the entire contents of which are hereby incorporated by reference.

### BACKGROUND OF THE INVENTION

1. Field of the Invention

The present disclosure herein relates to semiconductor memory devices, and more particularly, to nonvolatile memory devices, program methods thereof, and memory systems including the same.

2. Description of the Related Art

Semiconductor memory devices store data and allow host devices to read the stored data. Semiconductor memory devices are classified into volatile memory devices and nonvolatile memory (NVM) devices.

Volatile memory devices lose the data stored therein when power supplied to them is interrupted. Examples of volatile memory devices include static random access memory (SRAM) devices, dynamic random access memory (DRAM) devices, and synchronous dynamic random access memory (SDRAM) devices. Nonvolatile memory devices retain data stored therein even when power supplied to them interrupted. Examples of the nonvolatile memory devices include read-only memory (ROM) devices, programmable read-only memory (PROM) devices, erasable programmable read-only memory (EPROM) devices, electrically erasable programmable read-only memory (EEPROM) devices, flash memory devices, phase-change random access memory (PRAM) devices, magnetic random access memory (MRAM) devices, resistive random access memory (RRAM) devices, and ferroelectric random access memory (FRAM) devices. Flash memory devices are classified into NOR-type flash memory devices and NAND-type flash memory devices.

A NVM device of a memory system may further include an error correction block. The error correction block detects and corrects an error in data read from the NVM device. An error correction block is provided to detect and correct the read errors. The error correction block may generate a parity bit stored with the data to correct a read error. The parity bit(s) may be stored in the memory cell array of the NVM device together with data. The error correction range of the error correction block increases as the number of parity bits increases.

### SUMMARY OF THE INVENTION

Exemplary embodiments of the invention provide nonvolatile memory devices including an additional storage circuit of a de-interleaving circuit, which can perform a method of interleaving-programming operations and deinterleaving-reading operation, and memory systems including the same. A nonvolatile memory device according to various exemplary embodiments performs interleaving of data to be stored in each wordline, or of data to be stored in multiple wordlines. The storage circuit of the interleaving circuit is configured to store program data to be written interleaved into the memory cell array during a write operation. The read/write circuit is configured to control the interleaved/deinterleaved data input/output between the memory cell array and the storage circuit. The write operation unit size may be the same or different from the read operation unit size. The storage circuit stores the program data of size integer k times a common divisor of a read operation unit size and a write operation unit size of the read/write circuit, wherein k may equal ‘m’ (the number of bits stored in each memory cell of the NVM).

In some exemplary embodiments of the invention, nonvolatile memory devices include: a memory cell array; a storage circuit configured to store program data to be written into the memory cell array; and a read/write circuit configured to control the data input/output between the memory cell array and the storage circuit, wherein the storage circuit stores the program data of integer k times of a common divisor of the read operation unit size and the write operation unit size of the read/write circuit.

In some embodiments, the nonvolatile memory devices further include a control logic circuit configured to control the read/write circuit such that the program data written into the storage circuit are interleaved and programmed in the memory cell array.

In other embodiments, the memory cell array stores ‘m’ bits per cell, first to m^{th} bits of the memory cells connected to the same wordline form first to m^{th} storage rows respectively, and each of the memory cells forms a storage column; the storage circuit stores the program data to be stored in at least one storage row of the memory cell array; and the control logic unit controls the read/write circuit to program the program data in at least one storage column of the memory cell array.

In further embodiments, the storage circuit stores the program data of integer k times of the greatest common divisor of the read operation unit size and the write operation unit size of the read/write circuit.

In still further embodiments, the storage circuit stores the program data of integer k times of the read operation unit size of the read/write circuit.

In still further embodiments, the storage circuit stores the program data of integer k times of the write operation unit size of the read/write circuit.

In various embodiments, the memory cell array includes variable-resistance memory cells.

In other embodiments of the invention, memory systems include: a nonvolatile memory device; and a controller including a storage circuit that stores program data to be written interleaved in the nonvolatile memory device, the controller being configured to control the nonvolatile memory device and, wherein the storage circuit stores the program data of integer k times of a common divisor of the read operation unit size and the write operation unit size of the nonvolatile memory device.

In some embodiments, the nonvolatile memory device stores ‘m’ bits per cell, first to m^{th} bits of the memory cells connected to the same wordline form first to m^{th} storage rows respectively, and each of the memory cells forms a storage column; the storage circuit stores the program data to be stored in at least one row of the memory cell array; and the controller controls the read/write circuit to program the program data in at least one storage column of the nonvolatile memory device.

In various embodiments, the nonvolatile memory device and the controller form a solid state drive (SSD).

The drawings illustrate exemplary embodiments of the invention and, together with the description, serve to explain principles of the invention.

Preferred embodiments of the invention will be described below in more detail with reference to the accompanying drawings. The invention may, however, be embodied in different forms and should not be construed as limited to the exemplary embodiments set forth herein. Rather, these embodiments are provided so that this disclosure will be thorough and complete, and will fully convey the scope of the invention to those skilled in the art.

Exemplary embodiments of the invention are nonvolatile memory devices include a memory cell array, a storage circuit storing program data to be written in the memory cell array, and a read/write circuit controlling the data input/output between the memory cell array and the storage circuit, wherein the storage circuit stores program data of integer times of a common divisor of the read operation unit size and the write operation unit size of the read/write circuit.

According to embodiments of the invention, memory systems include a nonvolatile memory device, and a controller controlling the nonvolatile memory device and including a storage circuit that stores program data to be written in the nonvolatile memory device, wherein the storage circuit stores program data of integer times of a common divisor of the read operation unit size and the write operation unit size of the nonvolatile memory device.

### BRIEF DESCRIPTION OF THE DRAWINGS

The accompanying drawings of exemplary embodiments are included to provide a further understanding of the invention. In the drawings:

FIG. 1 is a block diagram of a memory system 10 according to an exemplary embodiment of the invention;

FIG. 2 is a block diagram of the nonvolatile memory device 200 in the memory system 10 of FIG. 1;

FIG. 3 is a block diagram of the memory cell array 210 illustrating a method of programming a plurality of pages of memory in the nonvolatile memory device 200 of

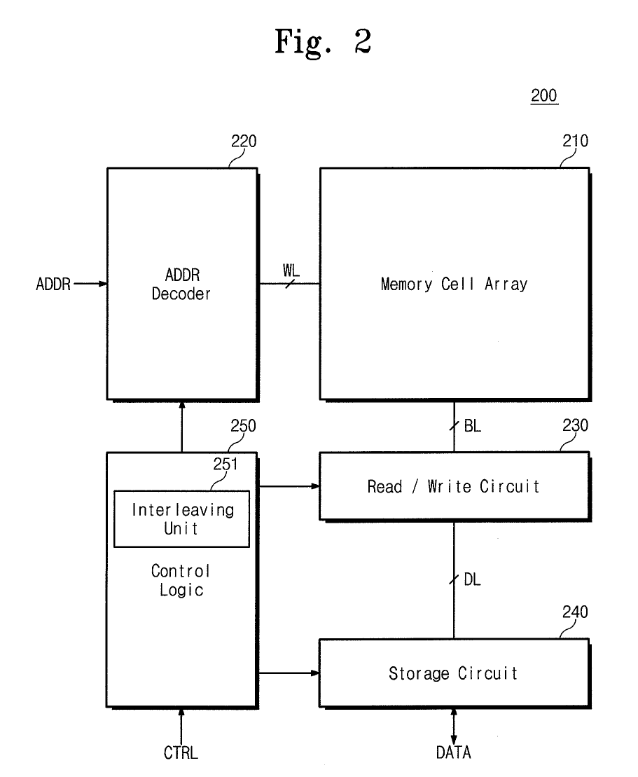

FIG. 2;

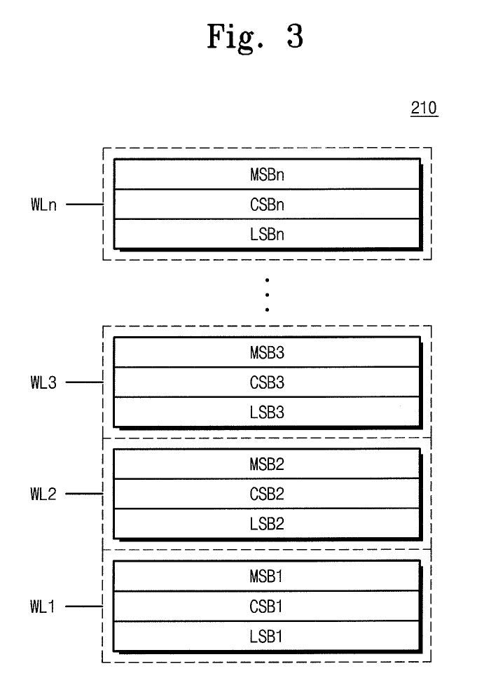

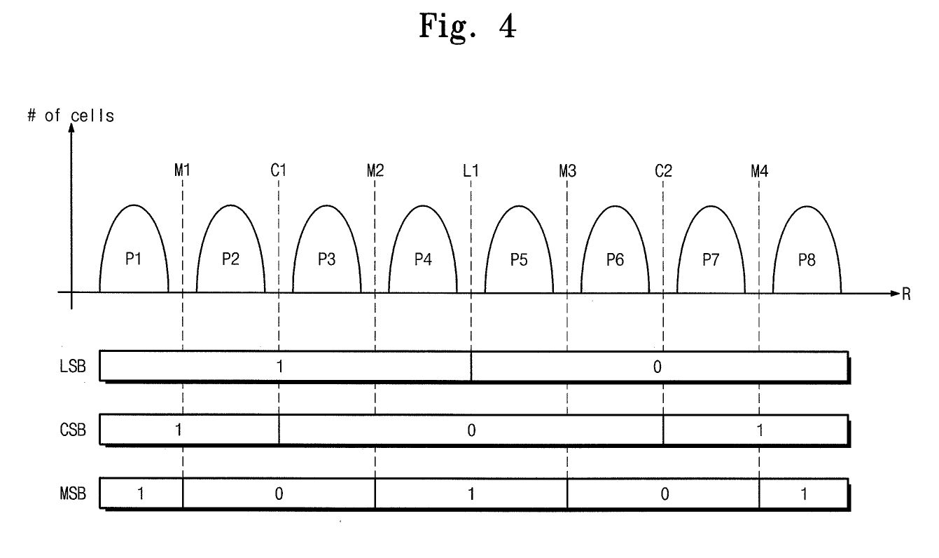

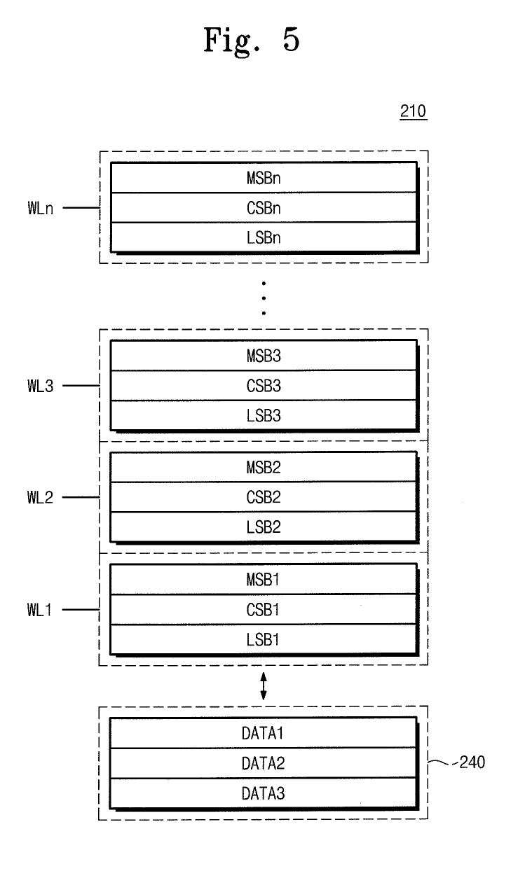

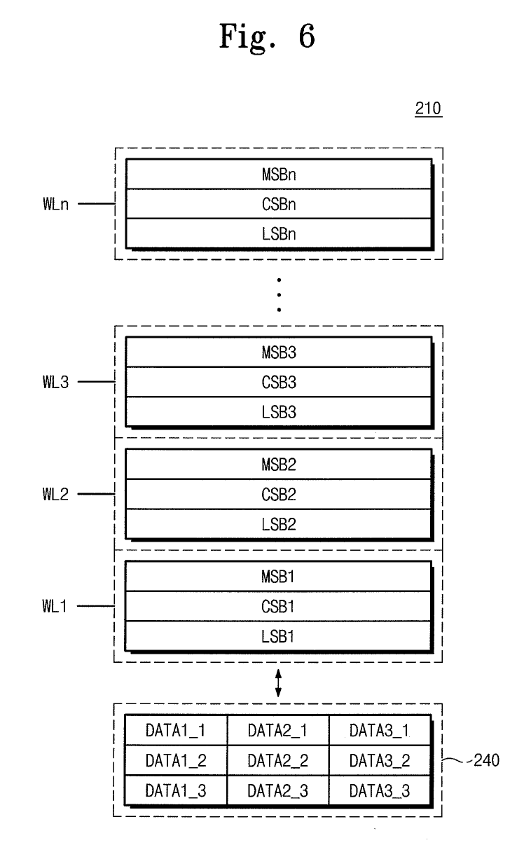

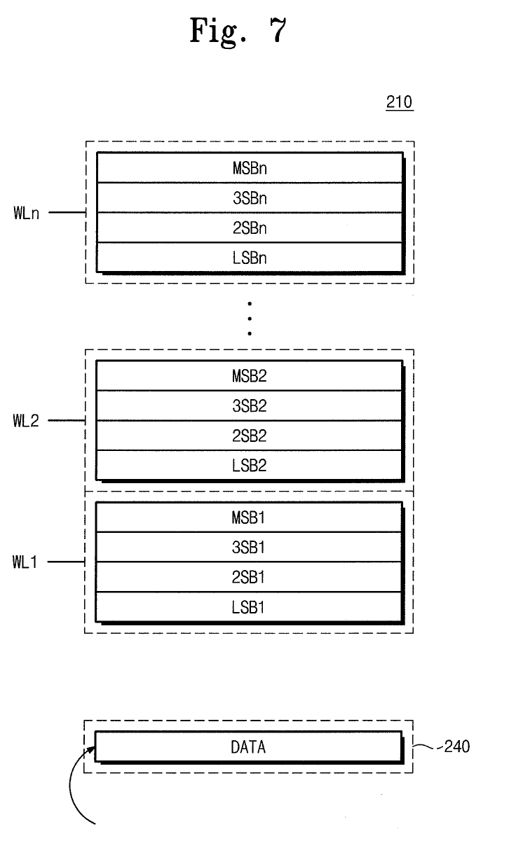

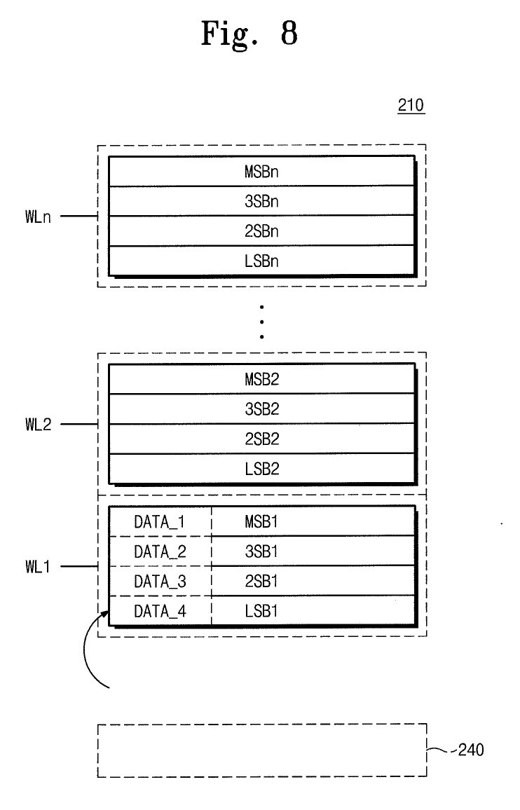

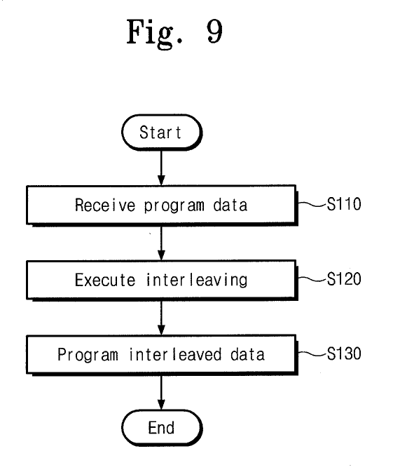

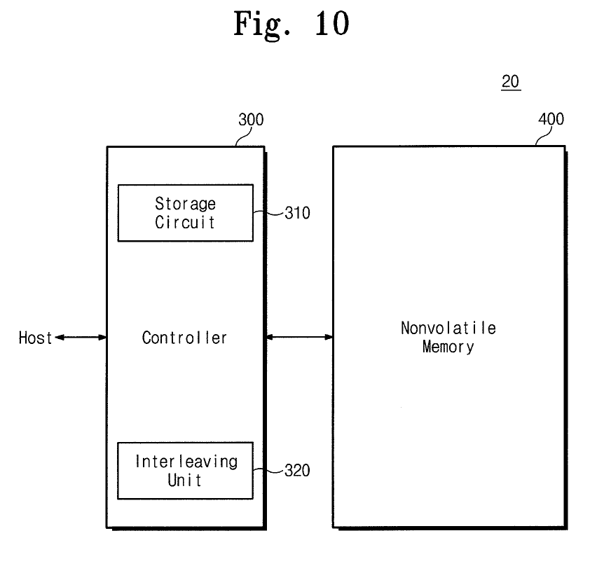

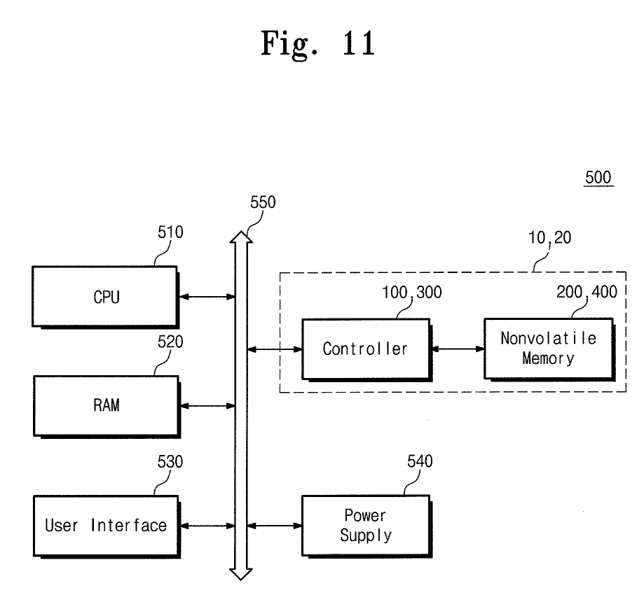

FIG. 4 is a characteristic distribution graph and diagrams illustrating a method of storing data in each of the memory cells in each page of the memory cell array 210 of FIG. 3 according to exemplary an embodiment of the invention;

FIG. 5 is a block diagram of the memory cell array 210 illustrating a method of programming a plurality of pages of memory in the nonvolatile memory device 200 of FIG. 2 according to another exemplary embodiment of the invention;

FIG. 6 is a block diagram of the memory cell array 210 illustrating a method of programming a plurality of pages of memory in the nonvolatile memory device 200 of FIG. 2 according to another exemplary embodiment of the invention according to another exemplary embodiment of the invention;

FIG. 7 and FIG. 8 are block diagrams of the memory cell array 210 illustrating a method of programming a plurality of pages of memory in the nonvolatile memory device 200 of FIG. 2 according to another exemplary embodiment of the invention according to another exemplary embodiment of the invention;

FIG. 9 is a flow chart of a method of programming according to an exemplary embodiment of the invention;

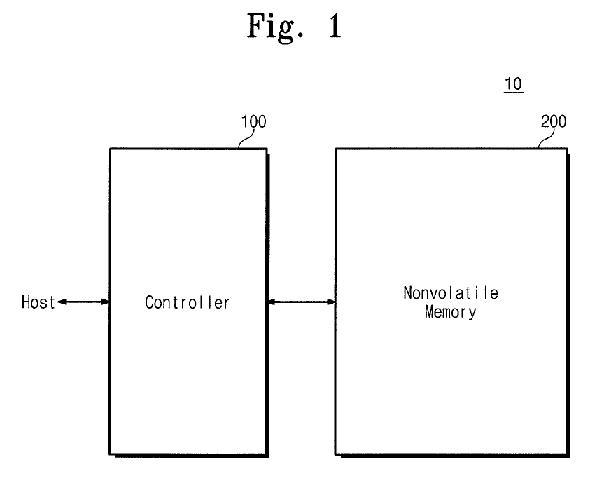

FIG. 10 is a block diagram of a memory system 20 according to another embodiment of the invention; and FIG. 11 is a block diagram of a computing system including the memory system of FIG. 1 or of FIG. 10.

### DETAILED DESCRIPTION OF EXEMPLARY EMBODIMENTS OF THE INVENTION

FIG. 1 is a block diagram of a memory system 10 according to an exemplary embodiment of the invention.

Referring to FIG. 1, a memory system 10 according to an exemplary embodiment of the invention includes a controller 100 and a nonvolatile memory device 200.

The controller 100 is connected to a host (not shown in FIG. 1, but see FIG. 11) and to the nonvolatile memory device 200. The controller 100 transfers data, read from the nonvolatile memory device 200, to the host and stores data, received from the host, in the nonvolatile memory device 200.

The controller 100 includes a conventional random access memory (RAM), a conventional processing unit, a conventional host interface, and a conventional memory interface. The RAM may be used as a working memory of the processing unit. The processing unit controls the overall operation of the controller 100.

The host interface may include a protocol for data exchange between the host and the controller 100. For example, the controller 100 may be configured to communicate with an external device (e.g., the host) through one of various interface protocols such as USB (Universal Serial Bus), MMC (Multimedia Card), PCI (Peripheral Component Interface), PCI-E (PCI-Express), ATA (Advanced Technology Attachment), Serial-ATA, eSATA (external Serial-ATA), Parallel-ATA, SCSI (Small Computer Small Interface), ESDI (Enhanced Small Disk Interface), and IDE (Integrated Drive Electronics).

The memory interface of the controller 100 interfaces with the nonvolatile memory device 200. The memory system 10 may further include a conventional error correction block. The error correction block may be configured to detect and correct an error in data read from the nonvolatile memory device 200.

FIG. 2 is a block diagram of a the nonvolatile memory device 200 in the memory system 10 of FIG. 1 according to an exemplary embodiment. The nonvolatile memory device 200 includes a memory cell array 210, an address decoder 220, a read/write circuit 230, a storage circuit 240, and a control logic circuit 250. The nonvolatile memory device 200 includes a memory cell array 210 for storing data, a read/write circuit for reading/writing data from/in the memory cell array, an address decoder for decoding an address received form an external device (e.g., host) and transferring the same to the read/write circuit, and a control logic circuit for controlling the overall operation of the nonvolatile memory device 200.

The memory cell array 210 is connected through word lines WL to the address decoder 220 and is connected through bit lines BL to the read/write circuit 230. The memory cell array 210 includes a plurality of memory cells. For example, each row of the memory cells are connected to one of the word lines WL, and each of the columns of the memory cells is connected to one of the bit lines BL. Each of the memory cells may be configured to store one or more bits per cell.

The address decoder 220 is connected through the word lines WL to the memory cell array 210. The address decoder 220 operates under the control of the control logic circuit 250. The address decoder 220 receives an address ADDR from an external device and selects a memory block and/or memory page (including a selected wordline) corresponding to the address ADDR. For example, the address ADDR is transferred to the controller 100 of FIG. 1. The address decoder 220 decodes a row address among the received addresses ADDR to select a word line WL. The address decoder 220 decodes a column address among the received addresses ADDR and transfers the same to the read/write circuit 230. For example, the address decoder 220 includes a row decoder, a column decoder, and an address buffer.

The read/write circuit 230 is connected through the bit lines BL to the memory cell array 210 and is connected through data lines DL to the storage circuit 240.

The read/write circuit 230 operates in response to the control of the control logic circuit 250. The read/write circuit 230 receives the column address from the address decoder 220. The read/write circuit 230 selects the bit lines BL in response to the received column address.

For example, the read/write circuit 230 receives data from the storage circuit 240 and stores the received data in the memory cell array 210. As another example, the read/write circuit 230 reads data from the memory cell array 210 and transfers the read data to the storage circuit 240. As another example, the read/write circuit 230 reads data from a first region of the memory cell array 210 and stores the read data in a second region of the memory cell array 210. For example, the read/write circuit 230 performs a copy-back operation.

The read/write circuit 230 includes a conventional page buffer and a column selection circuit. The read/write circuit 230 may conventionally include a sense amplifier, a write driver, and a column selection circuit.

The storage circuit 240 is connected through the data lines DL to the read/write circuit 230. The storage circuit 240 operates in response to the control of the control logic circuit 250. The storage circuit 240 exchanges data with an external device. For example, the storage circuit 240 exchanges data with the controller 100 of FIG. 1. Data received from an external device are transferred through the data lines DL to the read/write circuit 230. Data received from the read/write circuit 230 are outputted to an external device.

The control logic circuit 250 is connected to the address decoder 220, the read/write circuit 230, and the storage circuit 240. The control logic circuit 250 controls the overall operation of the nonvolatile memory device 200. The control logic circuit 250 operates in response to a control signal CTRL received from an external device. For example, the control signal CTRL is received from the controller 100 of FIG. 1.

The control logic circuit 250 includes an interleaving unit 251. The interleaving unit 251 is configured to interleave data to be programmed. For example, the interleaving unit 251 is configured to interleave data stored in the storage circuit 240. For example, the interleaving unit 251 controls the read/write circuit 230 so that data stored in the storage circuit 240 are interleaved and programmed in the memory cell array 210. The storage circuit 240 is a storage circuit of an interleaving-deinterleaving circuit (hereinafter a “de-interleaving circuit” or “de/interleaving circuit”). The de-interleaving circuit may comprise the interleaving unit 251 and the storage circuit 240. Alternatively the de-interleaving circuit may comprise the storage circuit 240 and a processor (e.g., the control logic circuit 250 or an external processor) configured to execute software to interleave data to be programmed.

The interleaving unit 251 may be implemented in hardware of a dedicated digital circuit, an analog circuit, or a combination thereof. The interleaving unit 251 may be implemented as software code executed in the control logic circuit 250. The interleaving unit 251 may be implemented as a combination of hardware and software.

FIG. 3 is a block diagram of the memory cell array 210 illustrating a method of programming a plurality of pages of memory in the nonvolatile memory device 200 of FIG. 2. For simplicity's sake, individual memory cells are not illustrated in FIG. 3.

Referring to FIG. 3, memory cells (not illustrated) connected to word lines WL1˜WLn store a plurality of bits per cell (see FIG. 4). The memory cells connected to each word line of the memory cell array 210 comprise storage rows and storage columns.

The number of storage rows corresponding to one word line may be equal to the number ‘m’ of bits capable of being stored in each one memory cell of the memory cell array 210. The number of storage columns corresponding to one word line may be equal to the number of memory cells connected to the word line. The memory cells (not illustrated) connected to each respective word line comprise a plurality of storage row (in each memory page). For example, the least significant bits (LSBs) of the memory cells connected to the word line WL1 may form the lowest storage row LSB1. The central significant bits (CSBs) of the memory cells connected to the word line WL1 may form the central storage row CSB1. The most significant bits (MSBs) of the memory cells connected to the word line WL1 may form the highest storage row MSB1. For example, if each of the memory cells connected to the word line WL1 stores ‘m’ bits per cell, the memory cells connected to each word line WL (e.g., WL1) comprises ‘m’ storage rows.

Each of the memory cells may form a storage column in each memory page. For example, if p memory cells are connected to the word line WL1, the memory cells connected to the word line WL1 may form p storage columns. Thus, the memory cells connected to each word line of the memory cell array 210 may form storage rows and storage columns.

Likewise, the memory cells connected to the word lines WL2˜WLn may form a plurality of storage rows LSB1˜LSBn, CSB1˜CSBn and MSB1˜MSBn and storage columns.

It is illustrated in FIG. 3 that the memory cells connected to each word line form 3 storage rows. Thus, each of the memory cells in FIG. 3 store 3 bits per cell. However, it will be understood that the nonvolatile memory device 200 according to an exemplary embodiment is not limited to the structure of storing 3 bits per cell.

FIG. 4 is a threshold voltage distribution graph and diagrams illustrating a method of storing data in each of the memory cells in each page of the memory cell array 210 of FIG. 2 according to exemplary an embodiment of the invention.

In FIG. 4, the horizontal axis of the characteristic (e.g., threshold voltage) distribution graph represents the characteristic (e.g., threshold voltage)values of memory cells at each logic state, and the vertical axis represents the number of memory cells at each characteristic (e.g., threshold voltage). For example, if the nonvolatile memory device 200 is a flash memory device, a logic value indicated by a hill along the horizontal axis represents a threshold voltage range of programmed memory cells. As another example, if the nonvolatile memory device 200 is a variable-resistance memory device (e.g., RRAMs, PRAMs, MRAMs, and FRAMs), a logic value indicated by a hill along the horizontal axis represents a resistance R range.

Hereinafter, for simplicity's sake, it is assumed that the nonvolatile memory device 200 is a variable-resistance memory device. That is, it is assumed that each of the memory cells of the nonvolatile memory device 200 is programmable to have ‘m’ different resistance values to store different data values. However, the invention is not limited to a variable-resistance memory device. For example, it will be understood that the invention is also applicable to nonvolatile memory devices such as ROMs, PROMs, EPROMs, EEPROMs, flash memory devices, PRAMs, MRAMs, RRAMs, and FRAMs. For example, by controlling a programming current in a memory cell, a PRAM device is programmed to have a resistance value corresponding to the logic state P2. By controlling the programming current, an MRAM device may be programmed to have a resistance value corresponding to the logic state P2. By controlling the program current, an FRAM device may be programmed to have a resistance value corresponding to the logic state P2. By controlling a programming current, an RRAM device may be programmed to have a resistance value corresponding to the logic state P2.

It is illustrated in FIG. 4 that the memory cells have one of 8 logic states P1˜P8. Thus, it is illustrated in FIG. 4 that the memory cells store 3 bits of data per cell. However, it will be understood that the nonvolatile memory device 200 according to an exemplary embodiment is not limited to the structure of storing 3 bits of data per cell.

Referring to FIG. 4, each of the memory cells are programmed corresponding to one of the eight logic states P1˜P8. The logic states P1˜P8 correspond to the LSB ‘1’ or ‘0’, the CSB ‘1’ or ‘0’, and the MSB ‘1’ or ‘0’. For example, it is illustrated that the logic states P1˜P4 correspond to the LSB ‘1’ and the logic states P5˜P8 correspond to the LSB ‘0’.

For example, the variable-resistance memory device programs multi bits through one program operation. For example, the memory cells corresponding to the logic state P2 are programmed to store the LSB ‘1’, the CSB ‘1’, and the MSB ‘0’. The corresponding memory cells may store the LSB ‘1’, the CSB ‘1’, and the MSB ‘0’ through one program operation.

It is illustrated that the logic states P1˜P4 correspond to the LSB ‘1’. Also, it is illustrated that the logic states P5˜P8 correspond to the LSB ‘0’. The resistance of the memory cells is compared with a first resistance L1 to determine whether the corresponding memory cells store the LSB ‘1’ or ‘0’. The comparing of the resistance of the memory cells with the first resistance L1 is performed through a read operation. Thus, the LSB data of the memory cells in each memory page are determined by one read operation.

It is illustrated that the logic states P1, P2, P7 and P8 correspond to the CSB ‘1’. It is illustrated that the logic states P3˜P6 correspond to the CSB ‘0’. Thus, the resistance of the memory cells is compared with a second resistance C1 and a third resistance C2 to determine the CSB data of the memory cells. Thus, the CSB data of the memory cells are determined through two read operations.

It is illustrated that the logic states P1, P4, P5 and P8 correspond to the MSB ‘1’. And, it is illustrated that the logic states P2, P3, P6 and P7 correspond to the MSB ‘0’. Thus, the resistance of the memory cells is compared with a fourth resistance M1, a fifth resistance M2, a sixth resistance M3 and a seventh resistance M4 to determine the MSB data of the memory cells. Thus, the NSB data of the memory cells are determined through four read operations.

Read error rates may differ between the highest storage row formed by the MSBs, the central storage row formed by the CSBs, and the lowest storage row formed by the LSBs of the memory cells. For example, it is assumed that an error rate in one read operation is ‘p’.

A read operation is performed one time to determine the LSB stored in the memory cells. Thus, a read error rate in the LSB may be p. A read operation is performed two times to determine the CSB stored in the memory cells. Thus, a read error rate in the CSB may be 2p. A read operation is performed four times to determine the MSB stored in the memory cells. Thus, a read error rate in the MSB may be 4p. As described above, a read error rate in the m^{th} bit (from the LSB) may be higher than a read error rate in the (m−1)^{th} bit.

An error correction block is provided to detect and correct the read errors. For example, the error correction block is provided in the controller 100 of FIG. 1. Alternatively, the error correction block is provided in the nonvolatile memory device 200 of FIG. 1. The error correction range of the error correction block may be set to be able to correct an error in the storage row with the highest error rate. Thus, the error correction range of the error correction block may be set to be able to correct an error in the highest storage row.

The error correction block may generate a parity bit stored with the data to correct a read error. The parity bit(s) may be stored in the memory cell array 210 of FIG. 2 together with data. The error correction block may correct a read error by using the parity bit(s) read from the memory cell array 210. For example, the error correction range of the error correction block increases as the number of parity bits increases.

If the error correction range of the error correction block is set according to the highest storage row, an unused parity bit may be generated in the storage row lower than the highest storage row. Thus, a necessary value of the error correction range of the error correction block may be greater in the storage row lower than the highest storage row, thus causing a waste of storage for parity bits.

The nonvolatile memory device prevents the above problem according to an exemplary embodiment by interleaving and storing program data in the memory cell array 210, which will be described below in detail with reference to FIGS. 5 and 6.

FIGS. 5 and 6 are diagrams illustrating a programming method according to an exemplary embodiment of the invention. A portion of the memory cell array 210 and the storage circuit 240 of FIG. 2 are illustrated in each of FIGS. 5 and 6.

Referring to FIG. 5, data are stored in the storage circuit 240. I In this exemplary embodiment, first data DATA1 are to be stored in the highest storage row MSB1 connected to the word line WL1 and second data DATA2 are to be stored in the central storage row CSB1 connected to the word line WL1 and third data DATA3 are to be stored in the lowest storage row LSB1 connected to the word line WL1.

The interleaving unit 251 (see FIG. 2) according to an exemplary embodiment is configured to interleave data stored in the storage circuit 240. The interleaving unit 251 is configured to interleave and store data in the memory cell array 210.

Data to be programmed in one storage row (e.g., DATA1) may be divided into ‘m’ groups. For example, ‘m’ is the number of bits capable of being stored in each one memory cell in each memory page. Thus, if the memory cell array 210 stores 3 bits per cell, ‘m’ equals 3, and the first data DATA1 to be programmed in one storage row may be divided into 3 groups. The divided first to m^{th} data may be stored in the first to m^{th} storage rows. Thus, the divided first to m^{th} data may be stored in at least one storage column.

Referring to FIG. 6, the first data DATA1 are divided into 3 groups DATA1_1, DATA1_2 and DATA1_3. The first data groups DATA1_1, DATA1_2 and DATA1_3 may be stored in the first to third storage rows MSB1, CSB1 and LSB1 respectively. Thus, the first data groups DATA1_1, DATA1_2 and DATA1_3 may be stored in at least one storage column.

The second data DATA2 are divided into 3 groups DATA2_1, DATA2_2 and DATA2_3. The second data groups DATA2_1, DATA2_2 and DATA2_3 may be stored in the first to third storage rows MSB1, CSB1 and LSB1. Thus, the second data groups DATA2_1, DATA2_2 and DATA2_3 may be stored in at least one storage column.

The third data DATA2 are divided into 3 groups DATA3_1, DATA3_2 and DATA3_3. The third data groups DATA3_1, DATA3_2 and DATA3_3 may be stored in the first to third storage rows MSB1, CSB1 and LSB1. Thus, the third data groups DATA3_1, DATA3_2 and DATA3_3 may be stored in at least one storage column.

In a read operation, data may be read from at least one storage column connected to the word line WL1. At least one storage column, from which data are read, may correspond to at least one storage column in which the data groups are stored. The data groups may be read from the memory cells in which the data groups are stored.

The read data may be represented as illustrated in FIG. 6. For example, the interleaving unit 251 is configured to deinterleave the read data. The interleaving unit 251 is configured to deinterleave and read the data stored in the memory cell array 210.

The data DATA1_1, DATA2_1 and DATA3_1 may be read from the highest storage row MSB1. The data DATA1_2, DATA2_2 and DATA3_2 may be read from the central storage row CSB1. The data DATA1_3, DATA2_3 and DATA3_3 may be read from the lowest storage row LSB1.

The data DATA1_1, DATA1_2 and DATA1_3 read from the lowest, central and highest storage rows LSB1, CSB1 and MSB1 may be combined to form the data DATA1. The data DATA2_1, DATA2_2 and DATA2_3 read from the lowest, central and highest storage rows LSB1, CSB1 and MSB1 may be combined to form the data DATA2. The data DATA3_1, DATA3_2 and DATA3_3 read from the lowest, central and highest storage rows LSB1, CSB1 and MSB1 may be combined to form the data DATA3. Thus, the read error rates of the data DATA1˜DATA3 may be distributed and made uniform. Thus, the error correction function of stored parity bits can be prevented from being wasted due to the difference in error rate between the storage rows. In other words, the use of methods according to exemplary the embodiments of the invention can improve the efficiency of the error correction function of stored parity bits.

The nonvolatile memory device 200 according to an exemplary embodiment includes the storage circuit 240 configured to optimize the interleaving-program(write) and deinterleaving-read operations as described above. For example, the storage circuit 240 according to an exemplary embodiment is configured to store programming data in an amount corresponding to the read operation unit size and the write operation unit size of the nonvolatile memory device 200.

FIGS. 7 and 8 are diagrams illustrating the storage circuit 240 according to an exemplary embodiment of the invention. The memory cell array 210 and the storage circuit 240 are illustrated in FIGS. 7 and 8.

Referring to FIGS. 7 and 8, each memory cell in the memory cell array 210 stores 4 bits per cell. Thus, it is illustrated that the memory cells connected to each word line comprise 4 storage rows. However, it will be understood that memory cell arrays according to various other embodiments of the invention are not limited to the structure of storing 4 bits per cell.

Program data DATA are loaded into the storage circuit 240. Data stored in the storage circuit 240 are interleaved and then programmed (written) into the memory cells of the memory cell array 210. The data stored in the storage circuit 240 may be divided into ‘m’ groups. Herein, ‘m’ is the number of bits that can be stored in each memory cell of the memory cell array 210. Thus, as illustrated in FIGS. 7 and 8, if the memory cell array 210 stores 4 bits per cell, the program data loaded into the storage circuit 240 may be divided into 4 groups. The divided data may be programmed in at least one storage column of the memory cell array 210. For example, it is illustrated in FIG. 8 that the data are divided and then programmed in at least one storage column formed by the memory cells connected to each wordline (e.g., connected to the first word line WL1).

According to a first exemplary embodiment, the storage circuit 240 is configured to store programming data of integer ‘m’ times of the write operation unit size of the nonvolatile memory device 200. The integer is the number ‘m’ of bits that can be stored in each one memory cell of the nonvolatile memory device 200. In various exemplary embodiments of the invention, each memory page (word line) of the memory array in the nonvolatile memory device 200 may comprise a predetermined number of memory cells. In various exemplary embodiments of the invention, the number of memory cells that can be read (affecting the read operation unit size) may be not equal to the number of memory cells that can be programmed (affecting the write operation unit size) during each operation.

For a first example, it is assumed that 128 memory cells can be simultaneously read in each read operation of the nonvolatile memory device 200 (i.e., the read operation unit size equals 128) while it is also assumed that 128 memory cells can be simultaneously programmed in a write operation of the nonvolatile memory device 200 (i.e., the write operation unit size=the read operation unit size=128).

In various exemplary embodiments of the invention, the storage circuit 240 may be configured to store program data of integer ‘n’ times 128 bits (where integer k equals T, wherein T is the number of wordlines to be interleaved). For example, if T equals one wordline, it is assumed that the storage circuit 240 is configured to store 128 bits of program data. Referring to FIG. 7, the storage circuit 240 may be configured to store 128 bits of program data. The 128 bits of programming data loaded into the storage circuit 240 may be divided into ‘m’ groups. Herein, ‘m’ is the number of bits that can be stored in each one memory cell of the memory cell array 210. For example, if the nonvolatile memory device stores 4 bits per cell (i.e., =4), the 128-bits of programming data loaded into the storage circuit 240 may be divided into 4 groups. Each of the divided data may be of 32 bits.

Referring to FIG. 8, ‘m’ divided data may be stored in at least one storage column of the memory cell array 210. It is assumed that 128 memory cells can be simultaneously programmed. Thus, the m divided data groups can be simultaneously programmed in 32 storage columns (i.e., memory cells). For example, the first bit of the first to fourth group is programmed in the LSB (or the MSB) of the first memory cell. Likewise, it is assumed that that 128 memory cells can be simultaneously read. Thus, the data programmed in 32 storage columns (i.e., memory cells) can be simultaneously read. The read data may be deinterleaved in the storage circuit 240.

For another example, the storage circuit 240 may be configured to store m×128-bit program data (e.g., where k=T times ‘in’, and T equals one). Herein, ‘m’ is the number of bits that can be stored in each one memory cell of the nonvolatile memory device 200. The program data stored in the storage circuit 240 may be divided into ‘m’ groups. Each of the m groups may be of 128 bits. It is assumed that 128 memory cells of the nonvolatile memory device 200 can be simultaneously programmed. Thus, the m divided data groups (m×128 bits of program data) can be simultaneously programmed in 128 storage columns (i.e., memory cells).

In another example, the first bit of the first to m^{th} group is programmed in the LSB (or the MSB) of the first memory cell. Likewise, it is assumed that that 128 memory cells can be simultaneously read. Thus, the data programmed in 128 storage columns (i.e., memory cells) may be simultaneously read. Thus, if the storage circuit 240 is configured to store m×128 bits, the data stored in the storage circuit 240 may be programmed through one interleaving-program operation. Thus, it will be understood that the efficiency of the interleaving-program operation can improve.

In another example, the storage circuit 240 is configured to store data of integer multiples (e.g., ‘i’ times) of m×128 bits (e.g., k equals times ‘m’). The amount of data interleaved together increases as the value of ‘i’ increases. Thus, the beneficial affect of distributing the read error rates of the lowest pages, the central pages and the highest pages by the interleaving write and deinterleaving read operations may increase. Thus, the beneficial affect of the interleaving write and deinterleaving read operations may increase as the wordline factor ‘i’ increases.

If the wordline factor ‘i’ increases above a critical value, the incremental degree of increase in the beneficial effect of the interleaving write and deinterleaving read operations may decrease. Thus, the degree of an increase in the benefit of the interleaving write and deinterleaving read operations may increase until the factor ‘i’ reaches a critical value, and may decrease if the factor ‘i’ increases over the critical value. Thus, it will be understood that the size of the storage circuit 240 for the interleaving write and deinterleaving read operations may be set by a designer considering the beneficial effect of the interleaving write and deinterleaving read operations and the cost, complexity and integration density of the storage circuit 240.

As another example, it is assumed that 192 memory cells of the nonvolatile memory device 200 can be simultaneously programmed, while only 128 memory cells of the nonvolatile memory device 200 can be simultaneously read. Also, it is assumed that the memory cell array 210 can store four (m=4) bits per cell. The 192-bit program data may be loaded into the storage circuit 240. The 192-bit program data may be divided into four (m=4) groups. Each of the four (m=4) divided groups may be of 48 bits. Thus, the four (m=4) divided data groups can be simultaneously programmed in 48 storage columns (i.e., memory cells). For example, the first bit of the first to fourth group is programmed in the LSB (or the MSB) of the first memory cell. Likewise, it is assumed that that 128 memory cells can be simultaneously read. Thus, the data programmed in 48 memory cells can be simultaneously read.

In another example, it is assumed that the storage circuit 240 is configured to store m×192-bit program data. Here integer k equals ‘m’ and ‘m’ is the number of bits that can be stored in each one memory cell of the nonvolatile memory device 200. The m×192-bit program data stored in the storage circuit 240 may be divided into m groups. Each of the m groups may be of 192 bits. It is assumed that 192 memory cells of the nonvolatile memory device 200 can be simultaneously programmed. Thus, the divided data groups can be simultaneously programmed in 192 storage columns (i.e., memory cells).

For example, the first bit of the first to m^{th} group is programmed in the LSB (or the MSB) of the first memory cell. Likewise, it is assumed that that 128 memory cells can be simultaneously read. Thus, the data programmed in 192 storage columns (i.e., memory cells) may be read through at least two read operations. Thus, if the storage circuit 240 is configured to store m×192 bits, the data stored in the storage circuit 240 may be programmed through one interleaving-program operation. Thus, it will be understood that the efficiency of the interleaving program operation can be improved.

Where the storage circuit 240 is configured to store data of integer times (e.g., ‘i’ times) of m×192 bits (i.e., integer k equals ‘i’ times the amount of data interleaved increases as the value of ‘i’ increases. Thus, the beneficial affect of distributing the read error rates of the lowest pages, the central pages and the highest pages by the interleaving write and deinterleaving read operations may increase. Thus, the effect of the interleaving write and deinterleaving read operations may increase as the value of ‘i’ increases.

If the value of factor ‘i’ increases over a critical value, the degree of the incremental increase in the beneficial affect of the interleaving write and deinterleaving read operations may decrease. Thus, the degree of the incremental increase in the effect of the interleaving write and deinterleaving read operations may increase until the value of ‘i’ reaches a critical value, and may decrease if the value of factor ‘i’ increases over the critical value. Thus, it will be understood that the size of the storage circuit 240 for the interleaving write and deinterleaving read operations may be set by a designer considering the effect of the interleaving write and deinterleaving read operations and the cost, complexity and integration density of the storage circuit 240.

As another example, it is assumed that 128 memory cells of the nonvolatile memory device 200 can be simultaneously programmed, while 192 memory cells of the nonvolatile memory device 200 can be simultaneously read. Also, it is assumed that the memory cell array 210 can store 4 bits per cell (‘m’=4).

128-bit program data may be loaded into the storage circuit 240 (i.e., k equals one). The 128-bit program data may be divided into m=4 groups. Each of the m divided groups may be of 32 bits. It is assumed that 128 memory cells can be simultaneously programmed. Thus, the m divided data groups can be simultaneously programmed in 32 storage columns (i.e., memory cells). For example, the first bit of the first to fourth group is programmed in the LSB (or the MSB) of the first memory cell. Likewise, it is assumed that that 192 memory cells can be simultaneously read. Thus, the data programmed in 32 memory cells (i.e., memory cells) can be simultaneously read.

In another example, it is assumed that the storage circuit 240 is configured to store m×128-bit program data (i.e., k=‘m’). Herein, ‘m’ is the number of bits that can be stored in each one memory cell of the nonvolatile memory device 200. The program data stored in the storage circuit 240 may be divided into ‘m’ groups. Each of the m groups may be of 128 bits. It is assumed that 128 memory cells of the nonvolatile memory device 200 can be simultaneously programmed. Thus, the m divided data groups (comprising m×128 bits of program data) can be simultaneously programmed in 128 storage columns (i.e., memory cells).

In another example, the first bit of the first to m^{th} group is programmed in the LSB (or the MSB) of the first memory cell. Likewise, it is assumed that that 192 memory cells can be simultaneously read. Thus, the data programmed in 128 storage columns (i.e., memory cells) may be read through at least two read operations. Thus, if the storage circuit 240 is configured to store m×128 bits, the data stored in the storage circuit 240 may be programmed through one interleaving program operation. Thus, it will be understood that the efficiency of the interleaving-program operation can improve.

In another example, the storage circuit 240 is configured to store data of integer times (e.g., ‘i’ times) of m×128 bits (e.g., k=‘i’ times ‘m’). The amount of data interleaved may increase as the value of ‘i’ increases. Thus, the beneficial affect of distributing the read error rates of the lowest pages, the central pages and the highest pages by the interleaving write and deinterleaving read operations may increase. Thus, the effect of the interleaving write and deinterleaving read operations may increase as the value of ‘i’ increases.

If the value of ‘i’ increases over a specific value, the degree of the increase in the effect of the interleaving write and deinterleaving read operations may decrease. Thus, the degree of the increase in the beneficial affect of the interleaving write and deinterleaving read operations may increase until the value of ‘i’ reaches a specific value, and may decrease if the value of ‘i’ increases over the specific value. Thus, it will be understood that the size of the storage circuit 240 for the interleaving write and deinterleaving read operations may be set by a designer considering the beneficial affect of the interleaving write and deinterleaving read operations and the cost, complexity and integration density of the storage circuit 240.

As described above, the storage circuit 240 may be configured to store program data of integer k times the write operation unit size. For example, the memory cell array 210 may store ‘m’ bits per cell, and the integer k may equal ‘m’. In this case, it will be understood that the interleaving program and deinterleaving read operations can be performed without a waste of the storage space of the storage circuit 240. Also, it will be understood that the efficiency of the interleaving-program operation can improve.

Thus, it will be understood that the beneficial affect of interleaving can improve as the capacity of the storage circuit 240 increases. As described with reference to FIGS. 7 and 8, the data stored in the storage circuit 240 are interleaved and programmed in at least one storage column connected to the word line WL1. Thus, the interleaving operation may be performed in units of storage rows and storage columns of one word line WL 1. In this case, the difference in read error rate between the storage rows is compensated for.

It will be understood that an interleaving operation can be performed between multiple (T) word lines WL1˜WLn if the capacity of the storage circuit 240 increases to i times m times the number of memory cells per wordline. For example, if i=2, program data are interleaved and programmed in at least one storage row of the first and second word lines WL1 and WL2.

An interleaving operation may be performed between the storage columns and storage rows of only one word line WL1 (i.e., i=1). Thus, the difference in read error rate between the storage rows of one word line WL 1 may be compensated for. Also, where i=2, an interleaving operation may be performed between two word lines WL1 and WL2. Thus, any difference in read error rate between the word lines WL1 and WL2 may be compensated for.

According to a second exemplary embodiment, the storage circuit 240 is configured to store program data of integer ‘n’ times of the read operation unit size of the nonvolatile memory device 200. For example, the memory cell array 210 may store ‘m’ bits per memory cell, and the integer ‘n’ may equal ‘m’ (i.e., k=m). As described above, it will be understood that the efficiency of the storage circuit 240 for the interleaving program and deinterleaving read operations can increase if the storage circuit 240 is configured to store program data of integer ‘n’ times of the read operation unit size of the nonvolatile memory device 200. Also, it will be understood that the efficiency of the deinterleaving read operation can increase.

It will be understood that an interleaving program and deinterleaving read operation can be performed between multiple (i>1) word lines WL1˜WLn. Thus, it will be understood that any difference in read error rate between the word lines WL1 and WL2 can be compensated for.

According to a third exemplary embodiment, the storage circuit 240 is configured to store program data of integer ‘n’ times of a common divisor of the write operation unit size and the read operation unit size of the nonvolatile memory device 200. For example, the storage circuit 240 is configured to store program data of integer ‘n’ times the greatest common divisor of the write operation unit size and the read operation unit size of the nonvolatile memory device 200. For example, where the memory cell array 210 stores ‘m’ bits per memory cell, the integer ‘n’ may equal ‘m’.

It is assumed in an example that 128 memory cells of the nonvolatile memory device 200 can be simultaneously programmed (i.e., write operation unit size=128) while 128 memory cells of the nonvolatile memory device 200 can be simultaneously read (i.e., read operation unit size=128). Also, it is assumed that ‘m’ bits may be stored in each one memory cell of the nonvolatile memory device 200.

The common divisors of the read operation unit size and the write operation unit size include 1, 2, 4, 8, 16, 32, 64 and 128. Thus, the storage circuit 240 may be configured to store program data of integer ‘n’ times a selected one of 1, 2, 4, 8, 16, 32, 64 and 128 bits. For example, it will be understood that the storage circuit 240 may be configured to store program data of m (i.e., ‘n’=‘m’) times any one of 1, 2, 4, 8, 16, 32, 64 and 128 bits.

The one greatest common divisor of the read operation unit size and the write operation unit size is 128. Thus, it will be understood that the storage circuit 240 may be configured to store program data of (k times 128) bits. For example, it will be understood that the storage circuit 240 may be configured to store program data of ‘m’ times 128 bits (where ‘n’=‘i’ times ‘m’, and T equals one).

In another example, it is assumed that 64 memory cells of the nonvolatile memory device 200 can be simultaneously programmed (i.e., the write operation unit size=64) while 128 memory cells of the nonvolatile memory device 200 can be simultaneously read (i.e., the read operation unit size=128). Also, it is assumed that ‘m’ bits are be stored in each one memory cell of the nonvolatile memory device 200.

The common divisor of the read operation unit size and the write operation unit size includes 1, 2, 4, 8, 16, 32 and 64, and where the greatest common divisor of the read operation unit size and the write operation unit size is 64. Thus, the storage circuit 240 may be configured to store program data of integer k times of one of 1, 2, 4, 8, 16, 32 and 64 bits. For example, it will be understood that the storage circuit 240 may be configured to store program data of ‘m’ times one of 1, 2, 4, 8, 16, 32 and 64 bits (i.e., k=m).

Where the greatest common divisor of the read operation unit size and the write operation unit size is 64, it will be understood that the storage circuit 240 may be configured to store k times 64 bits of program data. For example, the storage circuit 240 may be configured to store (‘m’ times 64) bits of program data (i.e., where k=m).

As described above, it will be understood that the efficiency of the storage circuit 240 for the interleaving program and deinterleaving read operations can increase if the storage circuit 240 is configured to store program data of integer k times of a common divisor of the read operation unit size and the write operation unit size of the nonvolatile memory device 200. Also, it will be understood that the efficiency of the deinterleaving read operation can increase.

For example, the storage circuit 240 may be configured to store data of integer k times 128 bits (e.g., k=‘i’ times ‘m’). The amount of data interleaved may increase as n increases. Thus, the effect of distributing the read error rates of the lowest pages, the central pages and the highest pages by the interleaving write and deinterleaving read operations may increase. Thus, the effect of the interleaving write and deinterleaving read operations may increase as the value of n increases.

It will be understood that an interleaving program and deinterleaving read operation can be performed in ‘i’ wordlines among word lines WL1 ˜WLn. Thus, where i=2, it will be understood that the difference in read error rate between the word lines WL1 and WL2 can be compensated for.

As described above, the storage capacity of the storage circuit 240 according to the embodiments of the invention may be set to integer k times of the read operation unit size, to integer k times of the write operation unit size, or to integer k times of a common divisor of the read operation unit size and the write operation unit size. For example, where the memory cell array 210 may store ‘m’ bits in one memory cell, and the integer k may equal ‘m’.

FIG. 9 is a flow chart of a method of programming according to an exemplary embodiment of the invention.

Referring to FIGS. 2 and 9, program data are received (e.g., stored in the storage circuit 240) in step S110. For one example, the storage circuit 240 is configured to store received program data of integer k times the read operation unit size of the nonvolatile memory device 200. As another example, the storage circuit 240 is configured to store (integer k times the write operation unit size of the nonvolatile memory device 200) bits of the program data. As yet another example, the storage circuit 240 is configured to store (integer k times a common divisor of the read operation unit size and the write operation unit size of the nonvolatile memory device 200) bits of the program data. As still another example, the storage circuit 240 is configured to store (integer k times the greatest common divisor of the read operation unit size and the write operation unit size of the nonvolatile memory device 200) bits of the program data. The above integer k may equal i times the number ‘m’ of bits that can be stored in each one memory cell of the nonvolatile memory device 200.

In step S120, an interleaving operation is performed. For example, the interleaving unit 251 divides the stored program data, stored in the storage circuit 240, into ‘m’ groups. Herein, ‘m’ may be the number of bits that can be stored in each one memory cell of the nonvolatile memory device 200.

In step S130, the interleaved data are programmed in the memory cell array 210. For example, the data groups are stored in at least one storage column of the memory cell array 210. For example, the data groups are stored in ‘u’ storage columns (i.e., memory cells). Herein, ‘u’ may be the number of bits of each of the data groups.

FIG. 10 is a block diagram of a memory system 20 according to another embodiment of the invention.

Referring to FIG. 10, the memory system 20 includes a controller 300 and a nonvolatile memory device 400 according to another embodiment of the invention.

The controller 300 is similar to the controller 100 of FIG. 1 with the exception that the controller 300 includes a storage circuit 310 and an interleaving unit 320. Thus, a description of an overlap therebetween will be omitted for conciseness.

The storage circuit 310 is configured to store program data. The storage circuit 310 may operate in the same manner as the storage circuit 240 described with reference to FIGS. 1 to 9.

The interleaving unit 320 is configured to perform an interleaving-program operation and a deinterleaving-read operation. The interleaving unit 320 may operate in the same manner as the interleaving unit 251 described with reference to FIGS. 1 to 9. For example, the interleaving unit 320 may interleave program data stored in the storage circuit 310. The interleaved data may be transferred to the nonvolatile memory device 400. Data read from the nonvolatile memory device 400 may be stored in the storage circuit 310. The interleaving unit 320 may be configured to interleave data stored in the storage circuit 310.

For example, the storage circuit 310 may be configured to store (integer k times the read operation unit size of the nonvolatile memory device 400) bits of the program data. As another example, the storage circuit 310 may be configured to store program data of integer k times the write operation unit size of the nonvolatile memory device 400. As another example, the storage circuit 310 may be configured to store program data of integer k times of a common divisor of the read operation unit size and the write operation unit size of the nonvolatile memory device 400. As another example, the storage circuit 310 may be configured to store program data of integer k times of the greatest common divisor of the read operation unit size and the write operation unit size of the nonvolatile memory device 400. The integer k may equal the number ‘m’ of bits storable in each one memory cell of the nonvolatile memory device 400.

The interleaving unit 320 may be implemented as hardware of a digital circuit, an analog circuit, or a combination thereof. Alternatively, the interleaving unit 320 may be implemented as software code executed in the controller 300. The interleaving unit 320 may otherwise be implemented in as a combination of hardware and software. The nonvolatile memory device 400 may include a memory cell array, an address decoder, a read/write circuit, a data input/output circuit, and a control logic circuit.

As described with reference to controller 100 and memory device 200 of FIG. 1, the controller 300 and the nonvolatile memory device 400 may be employed within various electronic devices.

Referring to memory systems of FIGS. 2 and 10, the controller 100/300 and the nonvolatile memory device 200/400 may be integrated into one semiconductor integrated circuit (IC). For example, the controller 100/300 and the nonvolatile memory device 200/400 may be integrated into one semiconductor IC to implement a memory card chip. For example, the controller 100 and the nonvolatile memory device 200/400 may be integrated into one semiconductor IC to implement a PC card (e.g., PCMCIA (Personal Computer Memory Card International Association)), a compact flash card (CF), a smart media card (e.g., SM and SMC), a memory stick, a multimedia card (e.g., MMC, RS-MMC and MMCmicro), a SD card (e.g., SD, miniSD, microSD and SDHC), or a universal flash storage (UFS).

The controller 100/300 and the nonvolatile memory device 200/400 may be integrated into one semiconductor IC to implement the semiconductor device in a solid state drive (SSD) configured to store data. When the memory system 10/20 is used in an SSD, the operation speed of the host connected to the memory system 10 is high.

The nonvolatile memory device 200/400 or the memory system 10/20 may be mounted in various types of packages. Examples of the packages of the nonvolatile memory device 200 or the memory system 10 include Package on Package (PoP), Ball Grid Arrays (BGA), Chip Scale Packages (CSP), Plastic Leaded Chip Carrier (PLCC), Plastic Dual In-line Package (PDIP), Die in Waffle Pack, Die in Wafer Form, Chip On Board (COB), Ceramic Dual In-line Package (CERDIP), Plastic Metric Quad Flat Pack (MQFP), Thin Quad Flat Pack (TQFP), Small Outline Integrated Circuit (SOIC), Shrink Small Outline Package (SSOP), Thin Small Outline Package (TSOP), System In Package (SIP), Multi Chip Package (MCP), Wafer-level Fabricated Package (WFP), and Wafer-level Processed Stack Package (WSP).

FIG. 11 is a block diagram of a computing system 500 including the memory system 10 or of FIG. 1 or the memory system 20 of FIG. 10.

Referring to FIG. 11, a computing system 500 according to an exemplary embodiment of the invention includes a central processing unit (CPU) 510, a random access memory (RAM) 520, a user interface 530, a power supply unit 540, and the memory system 10/20.

The memory system 10/20 is electrically connected through a system bus 550 to the CPU 510, the RAM 520, the user interface 530, and to the power supply unit 540. Data, which are provided through the user interface 530 or processed by the CPU 510, are received by and stored in the memory system 10/20. The memory system 10/20 includes a controller 100/300 and a nonvolatile memory device 200/400 (see FIG. 1 and FIG. 10).

The memory system 10/20 may provided as a solid state drive (SSD), as a booting drive of the computing system 500. Although not illustrated in FIG. 11, those skilled in the art will readily understand that the computing system 500 may further include an application chipset and a camera image processor.

The memory system 10/20 may be included in computers, portable computers, laptop computers, UMPCs (Ultra Mobile PCs), net-books, PDAs, web tablets, wireless phones, mobile phones, smart phones, digital cameras, digital audio recorders, digital audio players, digital picture recorders, digital picture players, digital video recorders, digital video players, devices capable of transmitting/receiving information in wireless environments, one of various electronic devices constituting a home network, one of various electronic devices constituting a computer network, one of various electronic devices constituting a telematics network, or one of various components constituting a computing system (e.g., an SSD and a memory card).

As described above, the storage circuit of the nonvolatile memory device according to the invention is configured to store program data in an amount corresponding to the read operation unit size and the write operation unit size of the nonvolatile memory device, thereby making it possible to perform an interleaving program operation and a deinterleaving read operation.

The above-disclosed subject matter is to be considered illustrative and not restrictive, and the appended claims are intended to cover all modifications, enhancements, and other embodiments, which fall within the true spirit and scope of the invention. Thus, to the maximum extent allowed by law, the scope of the invention is to be determined by the broadest permissible interpretation of the following claims and their equivalents, and shall not be restricted or limited by the foregoing detailed description. In the claims, the terms i, k, and m are positive integers.

What is claimed is:

1. A nonvolatile memory device comprising:
a memory cell array;
a storage circuit of a de-interleaving circuit, configured to store data to be written interleaved into the memory cell array; and
a read/write circuit configured to write a write operation unit of the stored data into the memory cell array and configured to read a read operation unit of the data from the memory cell array

2. The nonvolatile memory device of claim 1, further comprising a control logic circuit configured to control the storage circuit and the read/write circuit such that the data stored in the storage circuit are interleaved and are then written into the memory cell array.

3. The nonvolatile memory device of claim 2, wherein
the memory cell array stores ‘m’ bits of the data per memory cell, first to m^{th} bits of the memory cells connected to the same word line form first to m^{th} storage rows respectively, and m of the memory cells each storage column includes at least one memory cell from each of the m storage rows;
the storage circuit stores the data to be written into at least one storage row of the memory cell array; and
the control logic unit controls the read/write circuit to write the stored data into at least one storage column of the memory cell array.

4. The nonvolatile memory device of claim 2, wherein the control logic circuit is further configured to control the storage circuit and the read/write circuit such that data read from the memory cell array are deinterleaved and then stored in the storage circuit.

5. The nonvolatile memory device of claim 2, wherein the write operation unit size and the read operation unit size have at least one common divisor and only one greatest common divisor, and wherein the storage circuit is configured to store (k times a common divisor) bits of the data, wherein k is an integer.

6. The nonvolatile memory device of claim 5, wherein the storage circuit is configured to store k times the greatest common divisor bits of the data, wherein k is greater than one.

7. The nonvolatile memory device of claim 6, wherein k equals T times ‘m’, wherein ‘i’ is the number of wordlines to be interleaved and T is greater than one.

8. The nonvolatile memory device of claim 5, wherein the storage circuit stores (k times the greatest common divisor) bits of the data.

9. The nonvolatile memory device of claim 1, wherein the storage circuit stores (k times the read operation unit size) bits of the data, wherein k is an integer.

10. The nonvolatile memory device of claim 1, wherein the storage circuit stores (k times the write operation unit size) bits of the data, wherein k is an integer.

11. The nonvolatile memory device of claim 1, wherein the memory cell array comprises variable-resistance memory cells.

12. A memory system comprising:
a nonvolatile memory device wherein the nonvolatile memory device stores ‘m’ bits per memory cell; and
a controller including a storage circuit configured to store data to be written interleaved into the nonvolatile memory device, the controller being configured to control the nonvolatile memory device,
wherein the storage circuit stores (k times a common divisor of the read operation unit size and the write operation unit size of the nonvolatile memory device) bits of the data to be interleaved, wherein k is an integer.

13. The memory system of claim 12, wherein the read operation unit size equals the write operation unit size, and wherein the storage circuit stores k times the write operation unit size and k equals ‘m’.

14. The memory system of claim 12, wherein the read operation unit size is not equal to the write operation unit size, and wherein the storage circuit stores (k times the greatest common divisor of the read operation unit size and the write operation unit size) and k equals ‘m’.

15. The memory system of claim 12, wherein the read operation unit size equals the write operation unit size, and wherein the storage circuit stores k times the write operation unit size, and wherein k equals ‘i’ times ‘m’, wherein ‘i’ equals the number of wordlines to be interleaved.

16. The memory system of claim 12, wherein
the first to m^{th} bits of the memory cells connected to the same wordline form first to m^{th} storage rows respectively, and each of the storage columns comprises m memory cells;
the storage circuit stores the program data to be stored in at least m storage rows of the memory cell array; and
the controller controls the read/write circuit to write the program data into at least one storage column of the nonvolatile memory device.

17. The memory system of claim 12, wherein the nonvolatile memory device and the controller form a solid state drive (SSD).

18. A method of writing data into memory cells of a nonvolatile memory device having a memory cell array in which each memory cell stores ‘m’ bits, the method comprising:
storing data to be written interleaved into the memory cell array; and
writing a write operation unit of the stored data interleaved into the memory cell array.

19. The method of claim 18, further comprising controlling a storage circuit and a read/write circuit so that the data stored to be written interleaved into the memory cell array is interleaved and then written into the memory cell array.
